(19) United States
(12) Patent Application Publication
(10) Pub. No.: US 2023/0247913 A1
(43) Pub. Date: Aug. 3, 2023

(54) LIGHT DETECTION ELEMENT, LIGHT SENSOR UNIT, AND RECEIVING DEVICE

(71) Applicant: TDK CORPORATION, Tokyo (JP)

(72) Inventors: Nobutaka NISHIO, Tokyo (JP); Tetsuya SHIBATA, Tokyo (JP); Tomohito MIZUNO, Tokyo (JP); Hideaki FUKUZAWA, Tokyo (JP)

(73) Assignee: TDK CORPORATION, Tokyo (JP)

(21) Appl. No.: 18/075,603

(22) Filed: Dec. 6, 2022

(30) Foreign Application Priority Data
Jan. 28, 2022 (JP) 2022-011922

(51) Int. Cl. H10N 50/80; H10B 61/00; G02B 1/00

(52) U.S. Cl. CPC H01L 43/02; H01L 27/22; G02B 1/007

(57) ABSTRACT

This light detection element includes a meta-lens that includes nanostructures which are two-dimensionally arranged; and a magnetic element that includes a first ferromagnetic layer, a second ferromagnetic layer, and a spacer layer sandwiched between the first ferromagnetic layer and the second ferromagnetic layer. Light which passes through the meta-lens is applied to the magnetic element.

### BACKGROUND

The disclosure relates to a light detection element, a light sensor unit, and a receiving device. Priority is claimed on Japanese Patent Application No. 2022-011922, filed Jan. 28, 2022, the content of which is incorporated herein by reference.

Photoelectric conversion elements are used in various applications.

For example, Patent Document 1 discloses a receiving device which receives an optical signal using a photodiode. For example, the photodiode is a pn junction diode or the like using a semiconductor pn junction. In addition, for example, Patent Document 2 discloses a light sensor using a semiconductor pn junction and an image sensor using this light sensor.

### PATENT DOCUMENTS

[Patent Document 1] Japanese Unexamined Patent Application, First Publication No. 2001-292107

[Patent Document 2] Specification of U.S. Pat. No. 9,842,874

### SUMMARY

Light sensors using a semiconductor PN junction are widely utilized, but new breakthroughs are required for further development.

It is desirable to provide a light detection element, a light sensor unit, and a receiving device having novelty. The following means are provided.

A light detection element according to a first aspect includes a meta-lens that includes nanostructures which are two-dimensionally arranged; and a magnetic element that includes a first ferromagnetic layer, a second ferromagnetic layer, and a spacer layer sandwiched between the first ferromagnetic layer and the second ferromagnetic layer. Light which passes through the meta-lens is applied to the magnetic element.

A light sensor unit according to a second aspect includes a plurality of light detection elements. Each of the light detection elements is the light detection element according to the first aspect.

A receiving device according to a third aspect includes the light detection element according to the first aspect.

### BRIEF DESCRIPTION OF THE DRAWINGS

FIG. 1 is a cross-sectional view of a light detection element according to a first embodiment.

FIG. 2 is a plan view of a meta-lens according to a first example.

FIG. 3 is a schematic view of one unit constituting the meta-lens according to the first example.

FIG. 4 is a plan view of a meta-lens according to a second example.

FIG. 5 is a schematic view of one unit constituting the meta-lens according to the second example.

FIG. 6 is an explanatory schematic view of operation of the light detection element according to the first embodiment.

FIG. 7 is an explanatory view of a first mechanism of a first operation example of the light detection element according to the first embodiment.

FIG. 8 is an explanatory view of a second mechanism of the first operation example of the light detection element according to the first embodiment.

FIG. 9 is an explanatory view of a first mechanism of a second operation example of the light detection element according to the first embodiment.

FIG. 10 is an explanatory view of a second mechanism of the second operation example of the light detection element according to the first embodiment.

FIG. 11 is an explanatory view of another example of the second operation example of the light detection element according to the first embodiment.

FIG. 12 is an explanatory view of another example of the second operation example of the light detection element according to the first embodiment.

FIG. 13 is a conceptual diagram of a light sensor device according to a first application example.

FIG. 14 is a view illustrating an example of a specific constitution of a light sensor unit according to the first application example.

FIG. 15 is a conceptual diagram of a cross section of the light sensor device according to the first application example.

FIG. 16 is a view illustrating an example of a specific constitution of the light sensor unit according to a first modification example.

FIG. 17 is a conceptual diagram of a cross section of a light sensor device according to a second modification example.

FIG. 18 is a conceptual diagram of a transceiver system according to a second application example.

FIG. 19 is a block diagram of a transceiver device according to the second application example.

FIG. 20 is an enlarged schematic view of a part in the vicinity of the light detection element of the transceiver device according to the second application example.

FIG. 21 is a conceptual diagram of another example of a communication system.

FIG. 22 is a conceptual diagram of another example of a communication system.

### DETAILED DESCRIPTION

Hereinafter, embodiments will be described in detail suitably with reference to the drawings. In drawings used in the following description, in order to make characteristics easy to understand, characteristic portions may be illustrated in an enlarged manner for the sake of convenience, and dimensional ratios or the like of each constituent element may differ from actual values thereof. Exemplary materials, dimensions, and the like illustrated in the following description are merely examples. The disclosure is not limited thereto and can be suitably changed and performed within a range in which the effects of the disclosure are exhibited.

Directions will be defined. A lamination direction of a magnetic element 10 will be regarded as a z direction, one direction within a plane orthogonal to the z direction will be regarded as an x direction, and a direction orthogonal to the x direction and the z direction will be regarded as a y direction. Hereinafter, the positive z direction may be expressed as “upward”, and the negative z direction may be expressed as “downward”. The positive z direction is a direction toward a meta-lens 20 from the magnetic element 10. The upward and downward directions do not necessarily coincide with the direction in which the force of gravity acts.

### First Embodiment

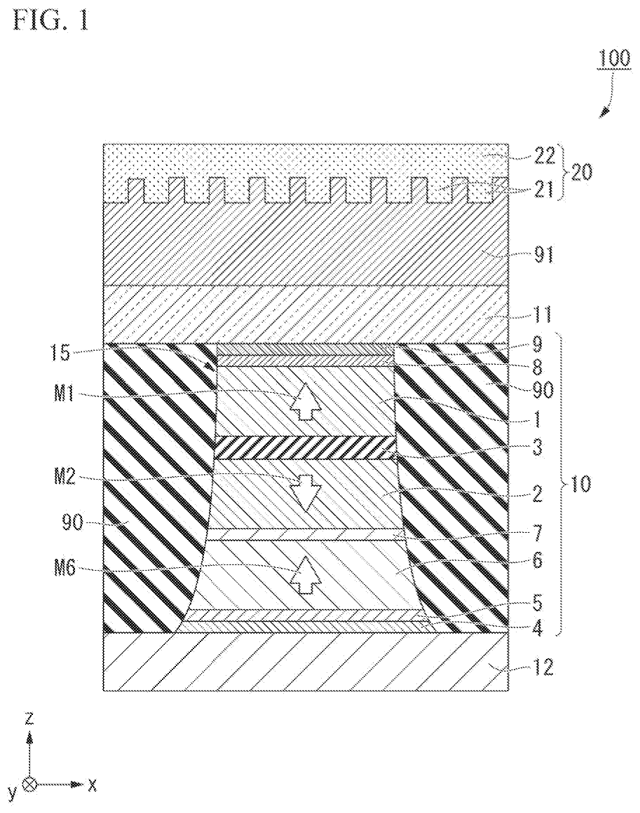

FIG. 1 is a cross-sectional view of a light detection element 100 according to a first embodiment. In FIG. 1, directions of magnetizations in an initial state of a ferromagnetic material are indicated by arrows.

The light detection element 100 has the magnetic element 10 and the meta-lens 20. Light which passes through the meta-lens 20 is applied to the magnetic element 10. The magnetic element 10 detects light applied to the magnetic element 10. The magnetic element 10 converts light applied to the magnetic element 10 into an electrical signal. The meta-lens 20 focuses light toward the magnetic element 10. For example, the magnetic element 10 is disposed at a focal position of light focused by the meta-lens 20. For example, an insulating layer 91 is provided between the magnetic element 10 and the meta-lens 20.

In this specification, light is not limited to visible rays and also includes infrared rays having a longer wavelength than visible rays and ultraviolet rays having a shorter wavelength than visible rays. The wavelength of visible rays is 380 nm or more and less than 800 nm, for example. The wavelength of infrared rays is 800 nm or more and 1 mm or less, for example. The wavelength of ultraviolet rays is 200 nm or more and less than 380 nm, for example.

The magnetic element 10 has at least a first ferromagnetic layer 1, a second ferromagnetic layer 2, and a spacer layer 3. The spacer layer 3 is positioned between the first ferromagnetic layer 1 and the second ferromagnetic layer 2. In addition to these, the magnetic element 10 may have a buffer layer 4, a seed layer 5, a third ferromagnetic layer 6, a magnetic coupling layer 7, a perpendicular magnetization inducing layer 8, a cap layer 9, and an insulating layer 90. The buffer layer 4, the seed layer 5, the third ferromagnetic layer 6, and the magnetic coupling layer 7 are positioned between the second ferromagnetic layer 2 and a second electrode 12, and the perpendicular magnetization inducing layer 8 and the cap layer 9 are positioned between the first ferromagnetic layer 1 and a first electrode 11. The insulating layer 90 is positioned between the first electrode 11 and the second electrode 12 and covers a part around a laminate 15.

For example, the magnetic element 10 is a magnetic tunnel junction (MTJ) element in which the spacer layer 3 is constituted using an insulating material. When light from the outside is applied to the magnetic element 10, a resistance value thereof changes. In the magnetic element 10, the resistance value in the z direction (the resistance value when a current flows in the z direction) changes in accordance with relative change between a state of a magnetization M1 of the first ferromagnetic layer 1 and a state of a magnetization M2 of the second ferromagnetic layer 2. Such an element is also referred to as a magnetoresistance effect element.

The first ferromagnetic layer 1 is a light detection layer of which the state of the magnetization changes when light is applied from the outside. The first ferromagnetic layer 1 is also referred to as a magnetization free layer. A magnetization free layer is a layer including a magnetic material of which the state of the magnetization changes when a predetermined energy from the outside is applied thereto. For example, a predetermined energy from the outside is light applied from the outside, a current flowing in the z direction of the magnetic element 10, or an external magnetic field. The state of the magnetization M1 of the first ferromagnetic layer 1 changes in accordance with the intensity of applied light.

The first ferromagnetic layer 1 includes a ferromagnetic material. For example, the first ferromagnetic layer 1 includes at least any of magnetic elements such as Co, Fe, and Ni. In addition to the magnetic elements described above, the first ferromagnetic layer 1 may include elements such as B, Mg, Hf, and Gd. For example, the first ferromagnetic layer 1 may be an alloy including a magnetic element and a non-magnetic element. The first ferromagnetic layer 1 may be constituted of a plurality of layers. For example, the first ferromagnetic layer 1 is a laminate in which a CoFeB alloy and a CoFeB alloy layer are sandwiched between Fe layers or a laminate in which a CoFeB alloy layer is sandwiched between CoFe layers. Generally, “ferromagnetism” includes “ferrimagnetism”. The first ferromagnetic layer 1 may exhibit ferrimagnetism. On the other hand, the first ferromagnetic layer 1 may exhibit ferromagnetism that is not ferrimagnetism. For example, a CoFeB alloy exhibits ferromagnetism that is not ferrimagnetism.

The first ferromagnetic layer 1 may be an in-plane magnetization film having an easy axis of magnetization in a direction within the film surface (any direction within an xy plane) or a perpendicular magnetization layer having an easy axis of magnetization in a direction perpendicular to the film surface (z direction).

The film thickness of the first ferromagnetic layer 1 is 1 nm to 5 nm, for example. The film thickness of the first ferromagnetic layer 1 may be 1 nm to 2 nm, for example. When the first ferromagnetic layer 1 is a perpendicular magnetization layer, if the film thickness of the first ferromagnetic layer 1 is small, perpendicular magnetic anisotropy application effects from layers on and beneath the first ferromagnetic layer 1 are enhanced, and the perpendicular magnetic anisotropy of the first ferromagnetic layer 1 increases. Namely, if the perpendicular magnetic anisotropy of the first ferromagnetic layer 1 is high, a force of the magnetization M1 tending to return in the z direction becomes stronger. On the other hand, if the film thickness of the first ferromagnetic layer 1 is large, perpendicular magnetic anisotropy application effects from layers on and beneath the first ferromagnetic layer 1 are relatively reduced, and the perpendicular magnetic anisotropy of the first ferromagnetic layer 1 decreases.

If the film thickness of the first ferromagnetic layer 1 is reduced, the volume of the ferromagnetic material decreases, and if it is increased, the volume of the ferromagnetic material increases. Magnetization responsiveness of the first ferromagnetic layer 1 when an energy from the outside is applied thereto is inversely proportional to the product (KuV) of a magnetic anisotropy (Ku) and a volume (V) of the first ferromagnetic layer 1. Namely, if the product of the magnetic anisotropy and the volume of the first ferromagnetic layer 1 becomes smaller, the responsiveness with respect to light increases. From such a viewpoint, to increase the reaction to light, the magnetic anisotropy of the first ferromagnetic layer 1 may be appropriately designed and then the volume of the first ferromagnetic layer 1 may be reduced.

When the film thickness of the first ferromagnetic layer 1 is larger than 2 nm, for example, an insertion layer made of Mo and W may be provided inside the first ferromagnetic layer 1. That is, a laminate in which a ferromagnetic layer, an insertion layer, and a ferromagnetic layer are laminated in order in the z direction may be adopted as the first ferromagnetic layer 1. The perpendicular magnetic anisotropy of the entire first ferromagnetic layer 1 increases due to interface magnetic anisotropy in interfaces between the insertion layer and the ferromagnetic layers. The film thickness of the insertion layer is 0.1 nm to 1.0 nm, for example.

The second ferromagnetic layer 2 is a magnetization fixed layer. A magnetization fixed layer is a layer made of a magnetic material of which the state of the magnetization is less likely to change than that of the magnetization free layer when a predetermined energy from the outside is applied thereto. For example, in a magnetization fixed layer, a direction of the magnetization when a predetermined energy from the outside is applied thereto is less likely to change than that of the magnetization free layer. In addition, for example, in a magnetization fixed layer, a magnitude of the magnetization is less likely to change than that of the magnetization free layer when a predetermined energy from the outside is applied thereto. For example, a coercive force of the second ferromagnetic layer 2 is greater than a coercive force of the first ferromagnetic layer 1. For example, the second ferromagnetic layer 2 has an easy axis of magnetization in the same direction as the first ferromagnetic layer 1. The second ferromagnetic layer 2 may be an in-plane magnetization film or may be a perpendicular magnetization layer.

For example, a material constituting the second ferromagnetic layer 2 is similar to that of the first ferromagnetic layer 1. For example, the second ferromagnetic layer 2 may be a multilayer film in which a Co layer having a thickness of 0.4 nm to 1.0 nm and a Pt layer having a thickness of 0.4 nm to 1.0 nm are alternately laminated several times. For example, the second ferromagnetic layer 2 may be a laminate in which a Co layer having a thickness of 0.4 nm to 1.0 nm, a Mo layer having a thickness of 0.1 nm to 0.5 nm, a CoFeB alloy layer having a thickness of 0.3 nm to 1.0 nm, and a Fe layer having a thickness of 0.3 nm to 1.0 nm are laminated in that order.

The magnetization of the second ferromagnetic layer 2 may be fixed, for example, through magnetic coupling with the third ferromagnetic layer 6 sandwiching the magnetic coupling layer 7. In this case, a combination of the second ferromagnetic layer 2, the magnetic coupling layer 7, and the third ferromagnetic layer 6 may be referred to as a magnetization fixed layer. Details of the magnetic coupling layer 7 and the third ferromagnetic layer 6 will be described below.

The spacer layer 3 is a layer disposed between the first ferromagnetic layer 1 and the second ferromagnetic layer 2. The spacer layer 3 is constituted of a layer constituted of an electric conductor, an insulator, or a semiconductor; or a layer including a current carrying point constituted of a conductor in an insulator. For example, the spacer layer 3 is a non-magnetic layer. The film thickness of the spacer layer 3 can be adjusted in accordance with orientation directions of the magnetization of the first ferromagnetic layer 1 and the magnetization of the second ferromagnetic layer 2 in the initial state, which will be described below.

When the spacer layer 3 is constituted using an insulating material, a material including aluminum oxide, magnesium oxide, titanium oxide, silicon oxide, or the like can be used as a material of the spacer layer 3. In addition, these insulating materials may include elements such as Al, B, Si, and Mg; or magnetic elements such as Co, Fe, and Ni. A high magnetoresistance change rate is obtained by adjusting the film thickness of the spacer layer 3 such that a high TMR effect is manifested between the first ferromagnetic layer 1 and the second ferromagnetic layer 2. In order to efficiently utilize a TMR effect, the film thickness of the spacer layer 3 may be approximately 0.5 to 5.0 nm and may be approximately 1.0 to 2.5 nm.

When the spacer layer 3 is constituted using a non-magnetic conductive material, a conductive material such as Cu, Ag, Au, or Ru can be used. In order to efficiently utilize a GMR effect, the film thickness of the spacer layer 3 may be approximately 0.5 to 5.0 nm and may be approximately 2.0 to 3.0 nm.

When the spacer layer 3 is constituted using a non-magnetic semiconductor material, a material such as zinc oxide, indium oxide, tin oxide, germanium oxide, gallium oxide, or ITO can be used. In this case, the film thickness of the spacer layer 3 may be approximately 1.0 to 4.0 nm.

When a layer including a current carrying point constituted of a conductor in a non-magnetic insulator is applied as the spacer layer 3, a structure including a current carrying point constituted of a non-magnetic conductor such as Cu, Au, or Al in a non-magnetic insulator constituted using aluminum oxide or magnesium oxide may be adopted. In addition, a conductor may be constituted using magnetic elements such as Co, Fe, and Ni. In this case, the film thickness of the spacer layer 3 may be approximately 1.0 to 2.5 nm. For example, the current carrying point is a columnar body having a diameter of 1 nm to 5 nm when view in a direction perpendicular to the film surface.

For example, the third ferromagnetic layer 6 is magnetically coupled to the second ferromagnetic layer 2. For example, magnetic coupling is anti-ferromagnetic coupling and occurs due to Ruderman-Kittel-Kasuya-Yosida (RKKY) interaction. The direction of the magnetization M2 of the second ferromagnetic layer 2 and the direction of a magnetization M6 of the third ferromagnetic layer 6 have an antiparallel relationship. For example, a material constituting the third ferromagnetic layer 6 is similar to that of the first ferromagnetic layer 1.

The magnetic coupling layer 7 is positioned between the second ferromagnetic layer 2 and the third ferromagnetic layer 6. For example, the magnetic coupling layer 7 is made of Ru, Ir, or the like.

The buffer layer 4 is a layer for relaxing lattice mismatch between different crystals. For example, the buffer layer 4 is a metal including at least one kind of element selected from the group consisting of Ta, Ti, Zr and Cr, or a nitride including at least one kind of element selected from the group consisting of Ta, Ti, Zr and Cu. More specifically, for example, the buffer layer 4 is made of Ta (single substance), a NiCr alloy, tantalum nitride (TaN), or copper nitride (CuN). For example, the film thickness of the buffer layer 4 is 1 nm to 5 nm. For example, the buffer layer 4 is amorphous. For example, the buffer layer 4 is positioned between the seed layer 5 and the second electrode 12 and comes into contact with the second electrode 12. The buffer layer 4 curbs an influence of crystal structures of the second electrode 12 on crystal structures of the second ferromagnetic layer 2.

The seed layer 5 enhances crystallinity of the layers laminated on the seed layer 5. For example, the seed layer 5 is positioned between the buffer layer 4 and the third ferromagnetic layer 6 and is provided on the buffer layer 4. For example, the seed layer 5 is made of Pt, Ru, Zr, or NiFeCr. The film thickness of the seed layer 5 is 1 nm to 5 nm, for example.

The cap layer 9 is provided between the first ferromagnetic layer 1 and the first electrode 11. The cap layer 9 may include the perpendicular magnetization inducing layer 8 which is laminated on the first ferromagnetic layer 1 and comes into contact with the first ferromagnetic layer 1. The cap layer 9 prevents damage to a lower layer during process steps and enhances the crystallinity of a lower layer at the time of annealing. The film thickness of the cap layer 9 is 10 nm or less, for example, such that sufficient light is applied to the first ferromagnetic layer 1.

The perpendicular magnetization inducing layer 8 induces the perpendicular magnetic anisotropy of the first ferromagnetic layer 1. For example, the perpendicular magnetization inducing layer 8 is made of magnesium oxide, W, Ta, Mo, or the like. When the perpendicular magnetization inducing layer 8 is made of magnesium oxide, in order to enhance the conductivity, magnesium oxide may be in an oxygen-deficient state. The film thickness of the perpendicular magnetization inducing layer 8 is 0.5 nm to 5.0 nm, for example.

For example, the insulating layer 90 is made of oxide, nitride, or oxynitride of Si, Al, or Mg. For example, the insulating layer 90 is made of silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), or the like.

For example, the first electrode 11 is disposed on the meta-lens 20 side of the magnetic element 10. Incident light is applied to the magnetic element 10 from the first electrode 11 side and is applied to at least the first ferromagnetic layer 1. The first electrode 11 is made of a conductive material. For example, the first electrode 11 is a transparent electrode having transparency with respect to light in a used wavelength range. For example, the first electrode 11 may allow 80% or more of light in a used wavelength range to be transmitted therethrough. For example, the first electrode 11 is made of oxide such as indium tin oxide (ITO), indium zinc oxide (IZO), zinc oxide (ZnO), or indium gallium zinc oxide (IGZO). The first electrode 11 may be constituted to have a plurality of columnar metals in these transparent electrode materials of these oxides. It is not essential to use the foregoing transparent electrode materials for the first electrode 11, and a metal material such as Au, Cu, or Al with a small film thickness may be used such that applied light reaches the first ferromagnetic layer 1. When a metal is used as a material of the first electrode 11, the film thickness of the first electrode 11 is 3 to 10 nm, for example. In addition, the first electrode 11 may have an antireflection film on an irradiation surface to which light is applied.

The second electrode 12 is made of a conductive material. For example, the second electrode 12 is constituted using a metal such as Cu, Al, or Au. A Ta layer or a Ti layer may be laminated on or beneath these metals. In addition, a laminated film made of Cu and Ta, a laminated film made of Ta, Cu, and Ti, and a laminated film made of Ta, Cu, and TaN may be used. In addition, TiN or TaN may be used for the second electrode 12. The film thickness of the second electrode 12 is 200 nm to 800 nm, for example.

The second electrode 12 may have transparency with respect to light applied to the magnetic element 10. Regarding a material of the second electrode 12, similar to the first electrode 11, for example, a transparent electrode material of oxide such as indium tin oxide (ITO), indium zinc oxide (IZO), zinc oxide (ZnO), or indium gallium zinc oxide (IGZO) may be used. Even when light is applied from a side of the first electrode 11, light may reach all the way to the second electrode 12 depending on the intensity of light. However, in this case, since the second electrode 12 is constituted to include a transparent electrode material of oxide, compared to a case in which the second electrode 12 is constituted using a metal, reflection of light in the interface between the second electrode 12 and a layer which comes into contact therewith can be curbed.

The meta-lens 20 has nanostructures 21. For example, the nanostructures 21 are formed on a base 22. The meta-lens 20 is a lens to which a metasurface is applied. The meta-lens 20 functions as a lens by controlling a phase distribution of light. A metasurface exhibits a function of a metamaterial due to a planar structure. A metamaterial is a medium having a negative refractive index or a medium designed to have a refractive index (permittivity, magnetic permeability) which does not exist in nature. Since a focal distance of the meta-lens 20 can be reduced, the light detection element 100 can be miniaturized. In addition, since a size of a focus of the meta-lens 20 can be reduced, light having a high energy can be efficiently applied to the magnetic element 10.

For example, the meta-lens 20 includes a dielectric in which surface plasmon excitation occurs. In addition, the meta-lens 20 transmits light in a bandwidth used. For example, the nanostructures 21 are made of titanium oxide or gallium nitride. When light incident on the light detection element 100 is infrared rays, the nanostructures 21 may be amorphous silicon. For example, the base 22 is made of silicon oxide or aluminum oxide.

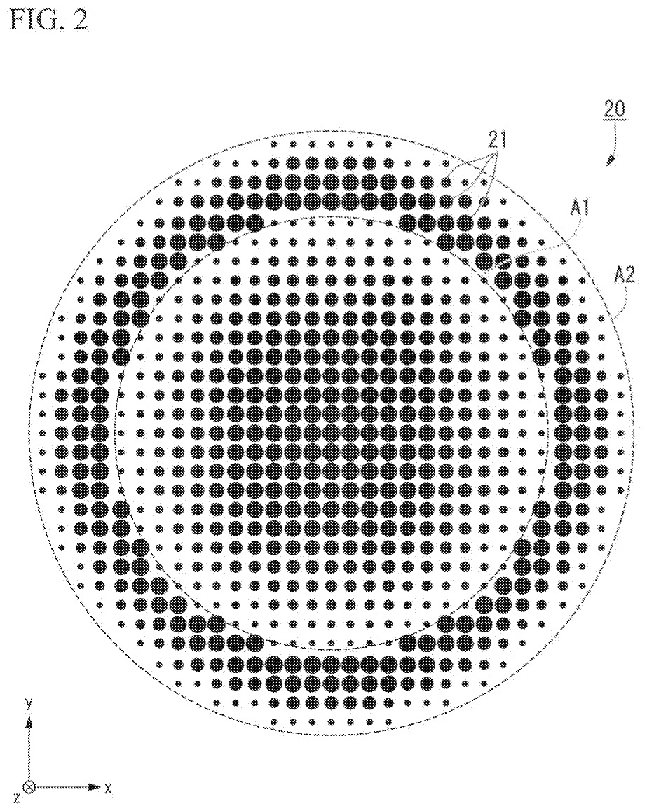

The nanostructures 21 are two-dimensionally arranged in an xy plane. An xy plane is an example of an arrangement surface on which the nanostructures 21 are arranged. FIG. 2 is a plan view of the meta-lens 20 according to a first example.

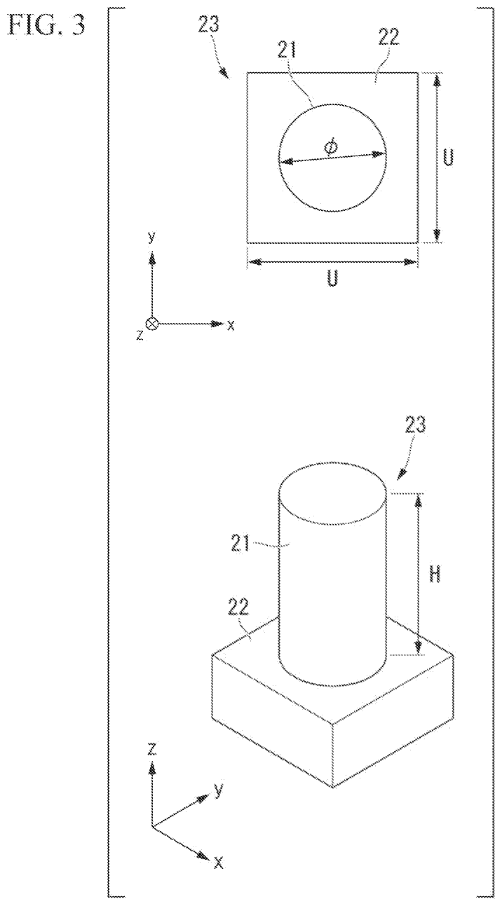

FIG. 3 is a schematic view of one unit 23 constituting the meta-lens 20 according to the first example. The upper diagram in FIG. 3 is a plan view in the z direction, and the lower diagram in FIG. 3 is a perspective view. Units 23 are arranged within the same plane, thereby serving as the meta-lens 20.

For example, the nanostructures 21 are pillars having diameters ϕ and heights H. In the meta-lens 20, these nanostructures 21 are regularly arranged at intervals U. In the nanostructures 21, the diameters ϕ have multiple values. In the nanostructures 21, the heights H may have only one value or may have multiple values. The diameters ϕ and the intervals U are equal to or shorter than the wavelength of light used. In the example illustrated in FIG. 3, the length of the base 22 in the x direction in one unit 23 is U, and the length thereof in the y direction is also U.

As illustrated in FIG. 2, for example, the meta-lens 20 has a first region A1 and an annular region A2 in a plan view in the z direction. The first region A1 has a circular shape, for example. The annular region A2 is provided on the outward side of the first region A1. An outer circumference of the annular region A2 and an outer circumference of the first region A1 are concentric circles, for example. The first region A1 internally has the nanostructures 21. The annular region A2 also internally has the nanostructures 21. The meta-lens 20 may not have the annular region A2.

For example, an area of each of the nanostructures 21 provided in the first region A1 in a plan view decreases toward the outward side from the center of the first region A1. For example, the diameters ϕ of the nanostructures 21 decrease toward the outward side from the center in the first region A1.

For example, an area of each of the nanostructures 21 provided in the annular region A2 in a plan view decreases toward an outer circumferential side from an inner circumferential side of the annular region A2. For example, the diameters ϕ of the nanostructures 21 decrease toward the outer circumferential side from the inner circumferential side in the annular region A2. For example, the areas of the nanostructures 21 arranged in the innermost circumference of the annular region A2 in a plan view are larger than the areas of the nanostructures 21 arranged in the outermost circumference of the first region A1 in a plan view.

In the meta-lens 20, the phase distribution of light can be controlled by adjusting disposition of the nanostructures 21, the size of each of the nanostructures 21, and the disposition intervals of the nanostructures 21.

For example, Table 1 shows the size of each of the nanostructures 21 and the disposition intervals of the nanostructures 21 w hen setting is performed with the diameter of the meta-lens 20 being 3 μm and the focal distance of light focused by the meta-lens 20 being 3 μm while the meta-lens 20 is constituted of only the first region A1. In this example, the nanostructures 21 are made of titanium oxide, and the insulating layer 91 is made of silicon oxide. In Table 1, λ represents the wavelength of light focused at the focal distance of 3 μm by the meta-lens 20, ϕₘₐₓ represents the diameter of the largest nanostructure 21, ϕₘᵢₙ represents the diameter of the smallest nanostructure 21, H represents the heights of the nanostructures 21, and U represents the intervals between the nanostructures 21.

TABLE 1

| | | | | | | | |
|---|---|---|---|---|---|---|---|
| λ (nm) | 1550 | 1310 | 880 | 633 | 530 | 430 | 290 |
| ϕₘₐₓ (nm) | 725 | 630 | 410 | 290 | 240 | 195 | 135 |
| ϕₘᵢₙ (nm) | 471 | 410 | 267 | 189 | 156 | 127 | 88 |
| H (nm) | 800 | 800 | 800 | 800 | 800 | 800 | 800 |
| U (nm) | 755 | 656 | 427 | 302 | 250 | 203 | 140 |

As shown in Table 1, even if the wavelength of incident light varies, the focal distance of the meta-lens 20 can be made the same by adjusting the sizes of the nanostructures 21 and the disposition intervals.

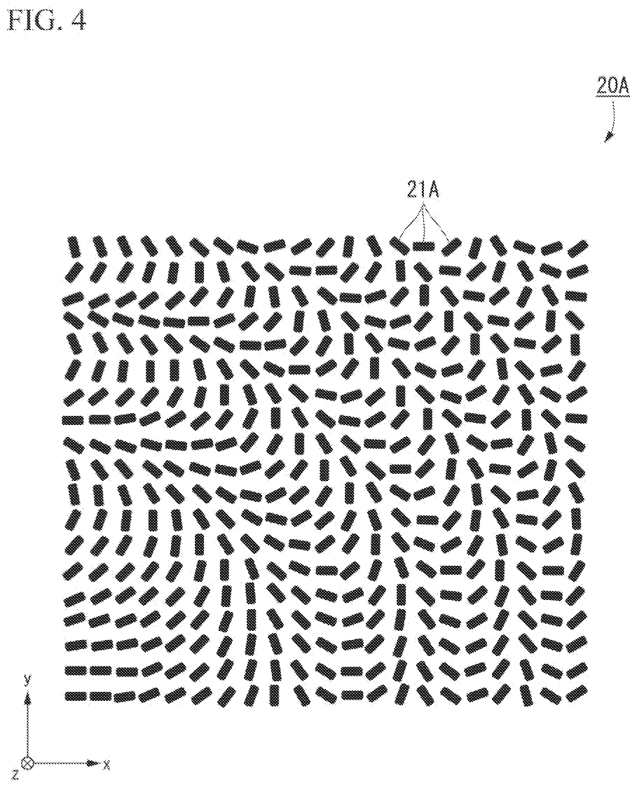

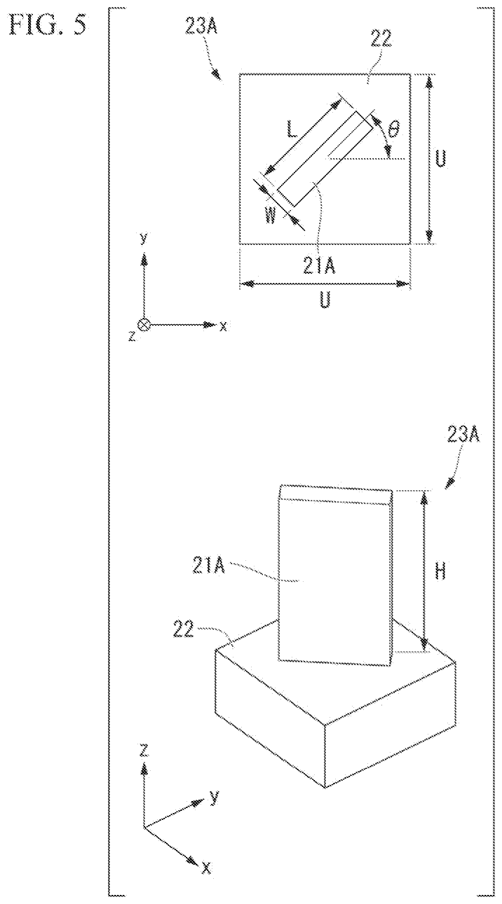

In addition, the structure of the meta-lens 20 is not limited to those illustrated in FIGS. 2 and 3. For example, one or more annular regions may further be provided on the outward side of the annular region A2 of the meta-lens 20 illustrated in FIG. 2. FIG. 4 is a plan view of a meta-lens 20A according to a second example. FIG. 5 is a schematic view of one unit 23A constituting the meta-lens 20A according to the second example. The upper diagram in FIG. 5 is a plan view in the z direction, and the lower diagram in FIG. 5 is a perspective view. Units 23A are arranged within the same plane, thereby serving as the meta-lens 20A.

Nanostructures 21A are two-dimensionally arranged in an xy plane. In a plan view of an xy plane, the shape of at least one of the nanostructures 21A in a plan view differs from the planar shape of another nanostructure 21A in a disposition angle. The disposition angle of the longitudinal direction of at least one of the nanostructures 21A is different from a disposition angle of the longitudinal direction of another nanostructure 21A.

For example, the shape of each of the nanostructures 21A in a plan view has a longitudinal direction and a transverse direction. The nanostructure 21A illustrated in FIG. 5 has a rectangular parallelepiped shape having a length of L in the longitudinal direction, a width of W in the transverse direction, and a height of H, and the shape thereof in a plan view is a rectangular shape having a length of L in the longitudinal direction and a width of W in the transverse direction. The length L, the width W, and the intervals U are equal to or shorter than the wavelength of light used. In the example illustrated in FIG. 5, the length of the base 22 in the x direction in one unit 23A is U, and the length thereof in the y direction is also U. In the meta-lens 20A, these nanostructures 21A are regularly arranged at the intervals U. The longitudinal direction of the nanostructures 21A is inclined at a disposition angle θ with respect to a reference axis (for example, the x direction). In the nanostructures 21A, the disposition angle θ may have multiple values. For example, the distribution thereof may have the regularity of a Pancharatnam-Berry geometric phase.

For example, Table 2 shows the size of each of the nanostructures 21A and the disposition intervals of the nanostructures 21A when setting is performed with the diameter of the meta-lens 20A being 3 μm and the focal distance of light focused by the meta-lens 20A being 3 μm while the distribution of the disposition angles θ of the nanostructures 21A satisfy the regularity of the Pancharatnam-Berry geometric phase. In this example, the nanostructures 21A are made of titanium oxide, and the insulating layer 91 is made of silicon oxide. In Table 2, λ represents the wavelength of light focused by the meta-lens 20 at the focal distance of 3 μm, W represents the widths of the nanostructures 21A in a plan view, L represents the lengths of the nanostructures 21A in a plan view, H represents the heights of the nanostructures 21A, and U represents the intervals between the nanostructures 21A.

TABLE 2

| | | | | | | | |
|---|---|---|---|---|---|---|---|
| λ (nm) | 1550 | 1310 | 880 | 633 | 530 | 430 | 290 |
| W (nm) | 145 | 140 | 115 | 95 | 80 | 45 | 40 |
| L (nm) | 555 | 510 | 455 | 380 | 265 | 165 | 135 |
| H (nm) | 600 | 600 | 600 | 600 | 600 | 600 | 600 |
| U (nm) | 605 | 565 | 505 | 430 | 315 | 215 | 185 |

As shown in Table 2, even if the wavelength of incident light varies, the focal distance of the meta-lens 20A can be made the same by adjusting the sizes of the nanostructures 21A and the disposition intervals.

The insulating layer 91 is provided between the magnetic element 10 and the meta-lens 20. The material of the insulating layer 91 is not particularly limited as long as light in a bandwidth used can be transmitted therethrough. For example, regarding the insulating layer 91, a substance similar to that of the insulating layer 90 can be used. The insulating layer 91 and the insulating layer 90 may be made of the same substances or different substances. In addition, the insulating layer 91 and the base 22 may be made of the same substances or different substances.

The light detection element 100 can be obtained by producing the second electrode 12, the magnetic element 10, the first electrode 11, the insulating layer 91, and the meta-lens 20 in order.

The magnetic element 10 is produced through a laminating step, a annealing step, and a processing step for each layer. First, the buffer layer 4, the seed layer 5, the third ferromagnetic layer 6, the magnetic coupling layer 7, the second ferromagnetic layer 2, the spacer layer 3, the first ferromagnetic layer 1, the perpendicular magnetization inducing layer 8, and the cap layer 9 are laminated on the second electrode 12 in order. For example, each layer is subjected to film formation by sputtering.

Next, the laminated film is annealed. An annealing temperature is 250° C. to 400° C., for example. Thereafter, the laminated film is processed into the laminate 15 which is columnar body by photolithography and etching. The laminate 15 may be a pillar or a prism. For example, the narrowest width when the laminate 15 is viewed in the z direction is 10 nm to 1,000 nm.

Next, the insulating layer 90 is formed such that a side surface of the laminate 15 is covered. The insulating layer 90 may be laminated multiple times. Next, an upper surface of the cap layer 9 is exposed from the insulating layer 90 by chemical mechanical polishing, and the first electrode 11 is subjected to film formation on the cap layer 9.

Next, the insulating layer 91 is subjected to film formation on the first electrode 11. A resist having a predetermined pattern formed thereon is formed on an upper surface of the insulating layer 91, and dry etching is performed. Through dry etching, a hole having a predetermined pattern is formed on the upper surface of the insulating layer 91. Next, the meta-lens 20 is formed by performing film formation while the hole is filled with the material constituting the nanostructures 21. The light detection element 100 is obtained through the foregoing step. When a wavelength filter 40 (which will be described below) is used, for example, a dielectric multilayer film which will serve as the wavelength filter 40 is subjected to film formation between the first electrode 11 and the insulating layer 91, for example. In this manner, in production of the light detection element 100, the magnetic element 10 and the meta-lens 20 can be consecutively formed through a vacuum film formation process.

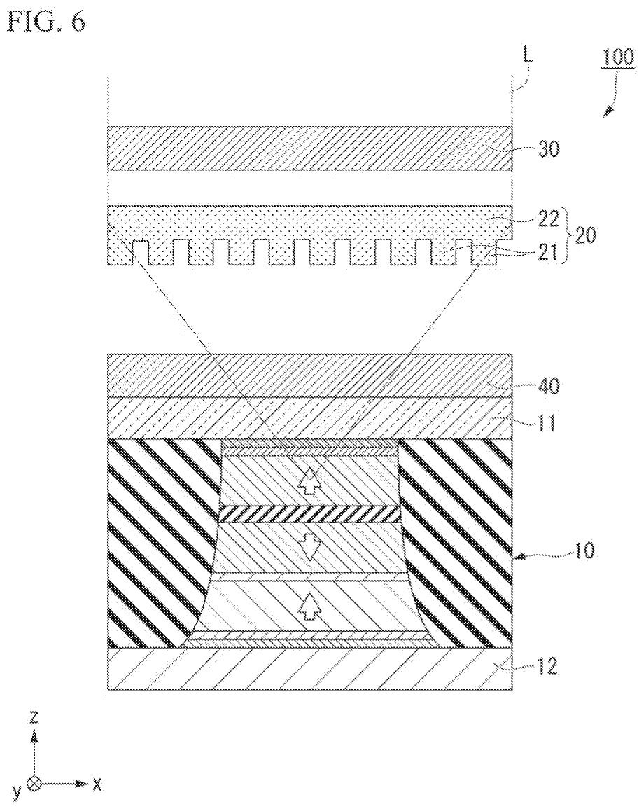

Next, operation of the light detection element 100 according to the first embodiment will be described. FIG. 6 is an explanatory schematic view of operation of the light detection element 100. In FIG. 6, the insulating layer 91 between the magnetic element 10 and the meta-lens 20 is omitted.

Light L incident on the light detection element 100 is focused by the meta-lens 20. As illustrated in FIG. 6, the light L incident on the meta-lens 20 may be light which passes through a polarization filter 30. The light detection element 100 may have the polarization filter 30 on a side of the meta-lens 20 opposite to the magnetic element 10. When the meta-lens 20A illustrated in FIG. 4 is used, the polarization filter 30 may be used. Even in a case of using the meta-lens 20A illustrated in FIG. 4, the polarization filter 30 may be omitted when light incident on the light detection element 100 is polarized light such as laser light.

The magnetic element 10 is disposed at the focal position of the light L in a bandwidth used focused by the meta-lens 20. For example, the focal position of the light L in a bandwidth used may overlap the first ferromagnetic layer 1. For example, when visible rays are used, the magnetic element 10 is disposed at the focal position of light in a particular wavelength range of a wavelength range of 380 nm or more and less than 800 nm. In addition, for example, when infrared rays are used, the magnetic element 10 is disposed at the focal position of light in a particular wavelength range of a wavelength range of 800 nm or more and less than 1,000 nm. In addition, for example, when ultraviolet rays are used, the magnetic element 10 is disposed at the focal position of light in a particular wavelength range of a wavelength range of 200 nm or more and less than 380 nm.

In addition, the light L applied to the magnetic element 10 may be light which pusses through the wavelength filter 40. The light detection element 100 may have the wavelength filter 40. For example, the wavelength filter 40 is disposed between the magnetic element 10 and the meta-lens 20 or on a side of the meta-lens 20 opposite to the magnetic element 10. Further, light L which passes through the meta-lens 20 is applied to the magnetic element 10.

An output voltage from the magnetic element 10 changes due to change in intensity of the light L applied to the first ferromagnetic layer 1. Change in resistance value of the first ferromagnetic layer 1, the second ferromagnetic layer 2, and the spacer layer 3 in the lamination direction contributes to change in output voltage from the magnetic element 10. In a first operation example, a case in which the intensity of light applied to the first ferromagnetic layer 1 has two levels including a first intensity and a second intensity will be described as an example. The intensity of light of the second intensity is set to be larger than the intensity of light of the first intensity. The first intensity may be zero in the case in which the intensity of light is applied to the first ferromagnetic layer 1.

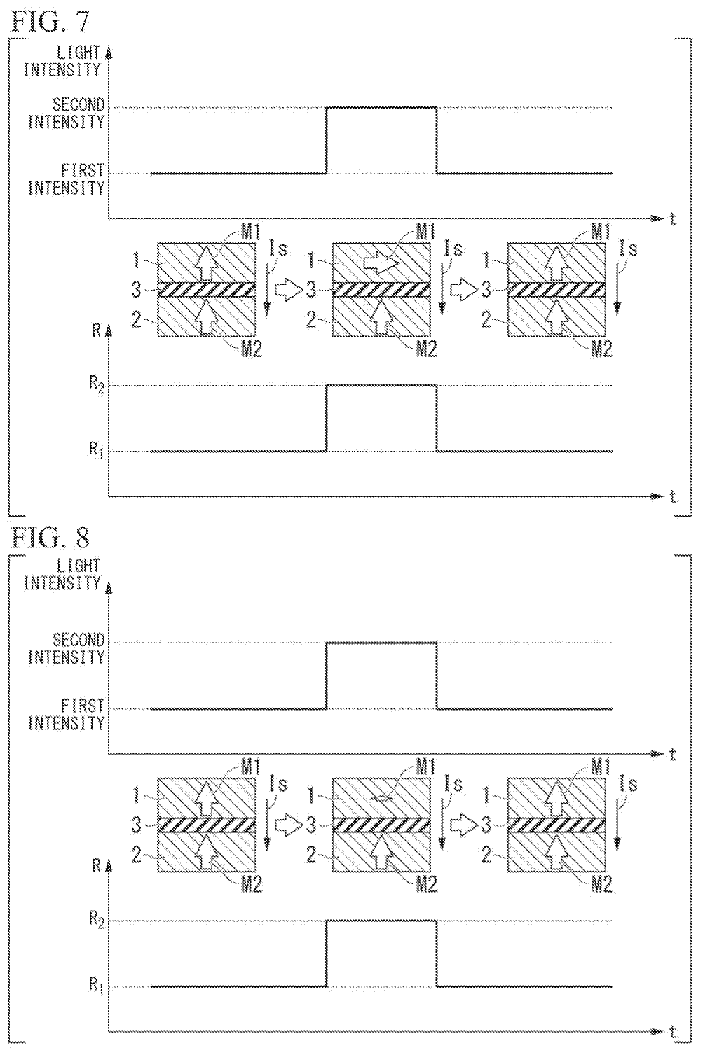

FIGS. 7 and 8 are explanatory views of the first operation example of the magnetic element 10. FIG. 7 is an explanatory view of a first mechanism of the first operation example, and FIG. 8 is an explanatory view of a second mechanism of the first operation example. In FIGS. 7 and 8, only the first ferromagnetic layer 1, the second ferromagnetic layer 2, and the spacer layer 3 of the magnetic element 10 are extracted and illustrated. In the upper graphs of FIGS. 7 and 8, the vertical axis represents an intensity of light applied to the first ferromagnetic layer 1, and the horizontal axis represents time. In the lower graphs of FIGS. 7 and 8, the vertical axis represents a resistance value of the magnetic element 10 in the z direction, and the horizontal axis represents time.

First, in a state in which light having the first intensity is applied to the first ferromagnetic layer 1 (which will hereinafter be referred to as an initial state), the magnetization M1 of the first ferromagnetic layer 1 and the magnetization M2 of the second ferromagnetic layer 2 have a parallel relationship. A first resistance value R₁ represents the resistance value of the magnetic element 10 in the z direction, and a first value represents the magnitude of an output voltage from the magnetic element 10. The resistance value of the magnetic element 10 in the z-direction is obtained by causing a sense current Is to flow through the magnetic element 10 in the z-direction to generate a voltage across both ends of the magnetic element 10 in the z-direction and using Ohm's law from a voltage value. An output voltage from the magnetic element 10 is generated between the first electrode 11 and the second electrode 12. In the case of the example illustrated in FIG. 7, the sense current Is flows from the first ferromagnetic layer 1 toward the second ferromagnetic layer 2. When the sense current Is flows in this direction, a spin transfer torque in the same direction as the magnetization M2 of the second ferromagnetic layer 2 acts on the magnetization M1 of the first ferromagnetic layer 1, and the magnetization M1 and the magnetization M2 become parallel to each other in the initial state. Also, it is possible to prevent the magnetization M1 of the first ferromagnetic layer 1 from being inverted during operation by causing the sense current Is to flow in the above direction.

Next, the intensity of light applied to the first ferromagnetic layer 1 changes from the first intensity to the second intensity. The second intensity is greater than the first intensity, and the magnetization M1 of the first ferromagnetic layer 1 changes from the initial state. The state of the magnetization M1 of the first ferromagnetic layer 1 in a state in which light is not applied to the first ferromagnetic layer 1 and the state of the magnetization M1 of the first ferromagnetic layer 1 in a state in which light having the second intensity is applied to the first ferromagnetic layer 1 differ from each other. For example, the state of the magnetization M1 includes the inclination angle with respect to the z direction, the magnitude, and the like.

For example, as illustrated in FIG. 7, when the intensity of light applied to the first ferromagnetic layer 1 changes from the first intensity to the second intensity, the magnetization M1 is inclined with respect to the z direction. In addition, for example, as illustrated in FIG. 8, when the intensity of light applied to the first ferromagnetic layer 1 changes from the first intensity to the second intensity, the magnitude of the magnetization M1 decreases. For example, when the magnetization M1 of the first ferromagnetic layer 1 is inclined with respect to the z direction due to the intensity of applied light, the inclination angle is larger than 0° and smaller than 90°.

When the magnetization M1 of the first ferromagnetic layer 1 changes from the initial state, the resistance value of the magnetic element 10 in the z direction represents a second resistance value R₂, and the magnitude of an output voltage from the magnetic element 10 represents a second value. The second resistance value R₂ is larger than the first resistance value R₁, and the second value of an output voltage is larger than the first value. The second resistance value R₂ is a value between the resistance value when the magnetization M1 and the magnetization M2 are parallel to each other (first resistance value R₁) and the resistance value when the magnetization M1 and the magnetization M2 are antiparallel to each other.

In the case illustrated in FIG. 7, a spin transfer torque in the same direction as the magnetization M2 of the second ferromagnetic layer 2 acts on the magnetization M1 of the first ferromagnetic layer 1. Therefore, the magnetization M1 tends to return to a state of being parallel to the magnetization M2, and the magnetic element 10 returns to the initial state when the intensity of light applied to the first ferromagnetic layer 1 changes from the second intensity to the first intensity. In the case illustrated in FIG. 8, when the intensity of light applied to the first ferromagnetic layer 1 returns to the first intensity, the magnitude of the magnetization M1 of the first ferromagnetic layer 1 returns to the original state, and the magnetic element 10 returns to the initial state. In both cases, the resistance value of the magnetic element 10 in the z direction returns to the first resistance value R₁. Namely, when the intensity of light applied to the first ferromagnetic layer 1 changes from the second intensity to the first intensity, the resistance value of the magnetic element 10 in the z direction changes from the second resistance value R₂ to the first resistance value R₁, and the magnitude of an output voltage from the magnetic element 10 changes from the second value to the first value.

An output voltage from the magnetic element 10 changes in response to the change in intensity of light applied to the first ferromagnetic layer 1, and the change in intensity of applied light can be converted into the change in output voltage from the magnetic element 10. That is, the magnetic element 10 can replace light with an electrical signal. For example, processing is performed while having an output voltage from the magnetic element 10 equal to or larger than a threshold as a first signal (for example, “1”) and having it smaller than the threshold as a second signal (for example, “0”).

Here, a case in which the magnetization M1 and the magnetization M2 are parallel to each other in the initial state has been described as an example. However, the magnetization M1 and the magnetization M2 may be antiparallel to each other in the initial state. In this case, the resistance value of the magnetic element 10 in the z direction decreases as the state of the magnetization M1 changes (for example, as change in angle from the initial state of the magnetization M1 increases). When a case in which the magnetization M1 and the magnetization M2 are antiparallel to each other is set as the initial state, the sense current Is may flow from the second ferromagnetic layer 2 toward the first ferromagnetic layer 1. When the sense current Is flows in this direction, a spin transfer torque in a direction opposite to the magnetization M2 of the second ferromagnetic layer 2 acts on the magnetization M1 of the first ferromagnetic layer 1, and the magnetization M1 and the magnetization M2 become antiparallel to each other in the initial state.

In the first operation example, a case in which light applied to the first ferromagnetic layer 1 has two levels including the first intensity and the second intensity has been described as an example. However, in a second operation example, a case in which the intensity of light applied to the first ferromagnetic layer 1 changes in a multi-level manner or an analog manner will be described.

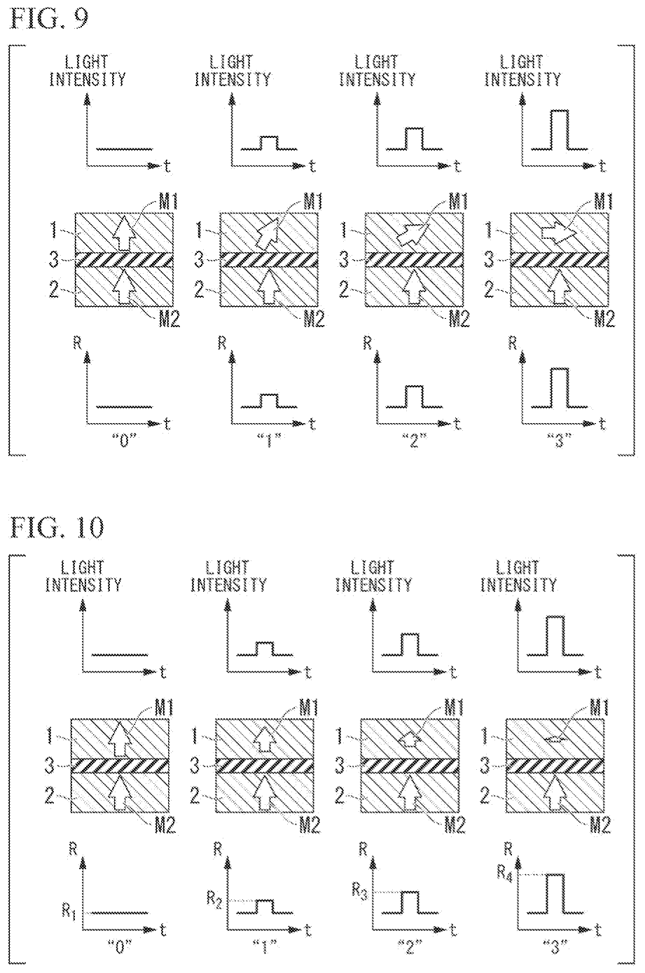

FIGS. 9 and 10 are explanatory views of the second operation example of the magnetic element 10 according to the first embodiment. FIG. 9 is an explanatory view of the first mechanism of the second operation example, and FIG. 10 is an explanatory view of the second mechanism of the second operation example. In FIGS. 9 and 10, only the first ferromagnetic layer 1, the second ferromagnetic layer 2, and the spacer layer 3 of the magnetic element 10 are extracted and illustrated. In the upper graphs of FIGS. 9 and 10, the vertical axis represents an intensity of light applied to the first ferromagnetic layer 1, and the horizontal axis represents time. In the lower graphs of FIGS. 9 and 10, the vertical axis represents a resistance value of the magnetic element 10 in the z direction, and the horizontal axis represents time.

In the case of FIG. 9, when the intensity of light applied to the first ferromagnetic layer 1 increases, the magnetization M1 of the first ferromagnetic layer 1 is inclined from the initial state due to an energy from the outside caused by applied light. Both the angles of the direction of the magnetization M1 of the first ferromagnetic layer 1 in a state in which light is not applied to the first ferromagnetic layer 1 and the direction of the magnetization M1 in a state in which light is applied thereto are larger than 0° and smaller than 90°.

When the magnetization M1 of the first ferromagnetic layer 1 is inclined from the initial state, the resistance value of the magnetic element 10 in the z direction changes. Further, an output voltage from the magnetic element 10 changes. For example, the resistance value of the magnetic element 10 in the z direction changes to the second resistance value R₂, a third resistance value R₃, or a fourth resistance value R₄ in accordance with the inclination of the magnetization M1 of the first ferromagnetic layer 1, and an output voltage from the magnetic element 10 changes to the second value, a third value, or a fourth value. The resistance value increases in order of the first resistance value R₁, the second resistance value R₂, the third resistance value R₃, and the fourth resistance value R₄. The output voltage from the magnetic element 10 increases in order of the first value, the second value, the third value, and the fourth value.

In the magnetic element 10, when the intensity of light applied to the first ferromagnetic layer 1 changes, an output voltage from the magnetic element 10 (resistance value of the magnetic element 10 in the z direction) changes. For example, when the first value (first resistance value R₁) is defined as “0”, the second value (second resistance value R₂) is defined as “1”, the third value (third resistance value R₃) is defined as “2”, and the fourth value (fourth resistance value R₄) is defined as “3”, information of four values can be read out from the magnetic element 10. Here, a case of reading out four values has been described as an example. However, the number of values to be read out can be freely designed by setting the threshold for an output voltage from the magnetic element 10 (resistance value of the magnetic element 10). In addition, an output analog value of the magnetic element 10 may be utilized as it is.

In addition, similarly in the case of FIG. 10 as well, when the intensity of light applied to the first ferromagnetic layer 1 increases, the magnitude of the magnetization M1 of the first ferromagnetic layer 1 decreases from the initial state due to an energy from the outside caused by applied light. When the magnetization M1 of the first ferromagnetic layer 1 decreases from the initial state, the resistance value of the magnetic element 10 in the z direction changes. Further, an output voltage from the magnetic element 10 changes. For example, the resistance value of the magnetic element 10 in the z direction changes to the second resistance value R₂, the third resistance value R₃, and the fourth resistance value R₄ in accordance with the magnitude of the magnetization M1 of the first ferromagnetic layer 1, and an output voltage from the magnetic element 10 changes 10 the second value, the third value, and the fourth value. Therefore, similar to the case of FIG. 9, differences between these output voltages (resistance values) can be read out from the light detection element 100 as multiple values or analog data.

In addition, in the case of the second operation example as well, similar to the case of the first operation example, when the intensity of light applied to the first ferromagnetic layer 1 returns to the first intensity, the state of the magnetization M1 of the first ferromagnetic layer 1 returns to the original state, and the magnetic element 10 returns to the initial state.

Here, a case in which the magnetization M1 and the magnetization M2 are parallel to each other in the initial state has been described as an example. However, in the second operation example as well, the magnetization M1 and the magnetization M2 may be antiparallel to each other in the initial state.

In addition, in the first operation example and the second operation example, a case in which the magnetization M1 and the magnetization M2 are parallel or antiparallel to each other in the initial state has been described as an example. However, the magnetization M1 and the magnetization M2 may be orthogonal to each other in the initial state. For example, a case in which the first ferromagnetic layer 1 in the initial state is an in-plane magnetization film having the magnetization M1 oriented in any direction in an xy plane and the second ferromagnetic layer 2 is a perpendicular magnetization layer having the magnetization M2 oriented in the z direction corresponds to this case. When the magnetization M1 is oriented in any direction within an xy plane due to the magnetic anisotropy and the magnetization M2 is oriented in the z direction, the magnetization M1 and the magnetization M2 are orthogonal to each other in the initial state.

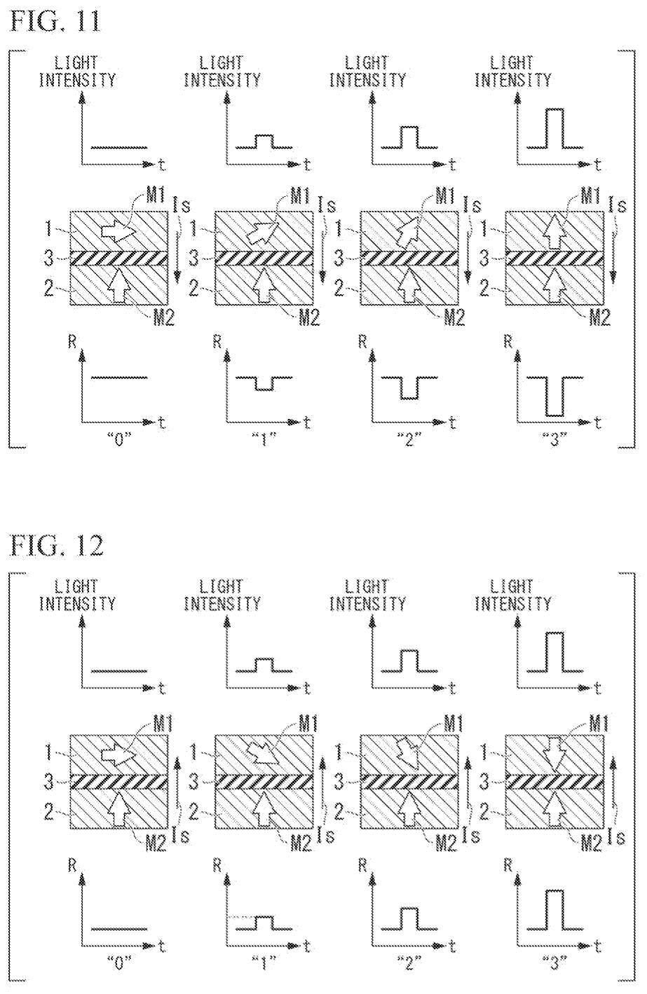

FIGS. 11 and 12 are explanatory views of another example of the second operation example of the magnetic element 10 according to the first embodiment. In FIGS. 11 and 12, only the first ferromagnetic layer 1, the second ferromagnetic layer 2. and the spacer layer 3 of the magnetic element 10 are extracted and illustrated. FIGS. 11 and 12 differ from each other in flowing direction of the sense current Is applied to the magnetic element 10. In FIG. 11, the sense current Is flows from the first ferromagnetic layer 1 toward the second ferromagnetic layer 2. In FIG. 12, the sense current Is flows from the second ferromagnetic layer 2 toward the first ferromagnetic layer 1.

In both cases of FIGS. 11 and 12, when the sense current Is flows in the magnetic element 10, a spin transfer torque acts on the magnetization M1 in the initial state. In the case of FIG. 11, a spin transfer torque acts such that the magnetization M1 becomes parallel to the magnetization M2 of the second ferromagnetic layer 2. In the case of FIG. 12, a spin transfer torque acts such that the magnetization M1 becomes antiparallel to the magnetization M2 of the second ferromagnetic layer 2. In both cases of FIGS. 11 and 12, in the initial state, since action on the magnetization M1 caused by the magnetic anisotropy is greater than action of a spin transfer torque, the magnetization M1 is directed in any direction within an xy plane.

When the intensity of light applied to the first ferromagnetic layer 1 increases, the magnetization M1 of the first ferromagnetic layer 1 is inclined from the initial state due to an energy from the outside caused by applied light. This is because the sum of the action on magnetization M1 caused by applied light and the action caused by a spin transfer torque becomes larger than the action caused by the magnetic anisotropy related to the magnetization M1. When the intensity of light applied to the first ferromagnetic layer 1 increases, the magnetization M1 in the case of FIG. 11 is inclined such that it becomes parallel to the magnetization M2 of the second ferromagnetic layer 2, and the magnetization M1 in the case of FIG. 12 is inclined such that it becomes antiparallel to the magnetization M2 of the second ferromagnetic layer 2. Since the direction of a spin transfer torque acting on the magnetization M1 varies, the inclination direction of the magnetization M1 in FIGS. 11 and 12 varies.

When the intensity of light applied to the first ferromagnetic layer 1 increases, in the case of FIG. 11, the resistance value of the magnetic element 10 decreases and an output voltage from the magnetic element 10 decreases. In the case of FIG. 12, the resistance value of the magnetic element 10 increases, an output voltage from the magnetic element 10 increases.

When the intensity of light applied to the first ferromagnetic layer 1 returns to the first intensity, the state of the magnetization M1 of the first ferromagnetic layer 1 returns to the original state due to the action on the magnetization M1 caused by the magnetic anisotropy. As a result, the magnetic element 10 returns to the initial state.

Here, an example in which the first ferromagnetic layer 1 is an in-plane magnetization film and the second ferromagnetic layer 2 is a perpendicular magnetization layer has been described. However, this relationship may be reversed. That is, in the initial state, the magnetization M1 may be oriented in the z direction, and the magnetization M2 may be oriented in any direction within an xy plane.

As described above, in the light detection element 100 according to the first embodiment, light is focused toward the magnetic element 10 by the meta-lens 20, and light can be replaced with an electrical signal by replacing light applied to the magnetic element 10 with an output voltage from the magnetic element 10.

In addition, the magnetization M1 of the first ferromagnetic layer 1 is more likely to change with respect to applied light as the volume of the first ferromagnetic layer 1 decreases. Namely, the magnetization M1 of the first ferromagnetic layer 1 is more likely to be inclined due to applied light or is more likely to decrease due to applied light as the volume of the first ferromagnetic layer 1 decreases. In other words, when the volume of the first ferromagnetic layer 1 is reduced, the magnetization M1 can be changed even with a slight amount of light. That is, the light detection element 100 according to the first embodiment can detect light with high sensitivity.

To be more exact, the changeability of the magnetization M1 is determined by the size of the product (KuV) of the magnetic anisotropy (Ku) and the volume (V) of the first ferromagnetic layer 1. As the KuV decreases, the magnetization M1 changes even with a smaller amount of light, and as the KuV increases, the magnetization M1 does not change unless a larger amount of light is applied. Namely, the KuV of the first ferromagnetic layer 1 is designed in accordance with the amount of light applied from the outside in an application use. When it is assumed to detect a very small amount of light (extremely small amount) such as photons, such a small amount of light can be detected by reducing the KuV of the first ferromagnetic layer 1. Detection of such a small amount of light is a great advantage because it becomes difficult in pn-junction semiconductors in the related art when the element size is reduced. Namely, photons can also be detected by reducing the volume of the first ferromagnetic layer 1, namely, by reducing the element area or thinning the film thickness of the first ferromagnetic layer 1 in order to reduce the KuV.

In addition, the amount of light focused on the magnetic element 10 by the meta-lens 20 increases as the area of the meta-lens 20 increases. In the magnetic element 10, since light can be replaced with an electrical signal even if the amount of applied light is small, the area of the meta-lens 20 can be reduced. The light detection element 100 can be integrated at a high density by reducing the area of the meta-lens 20 in accordance with the magnetic element 10.

The light detection element according to the foregoing embodiment can be applied to receiving devices of communication systems, light sensor devices such as image sensors, and the like.

### First Application Example

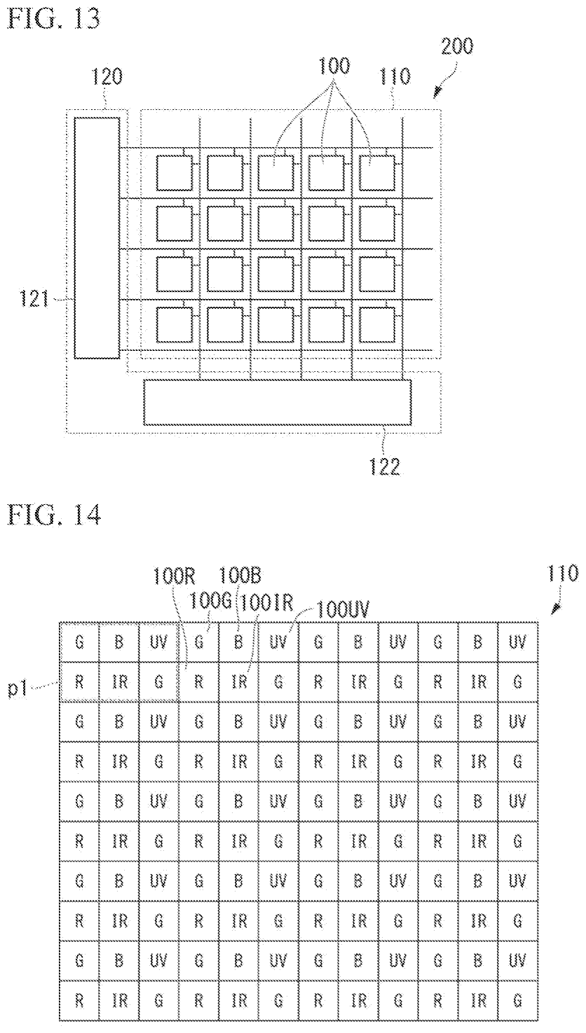

FIG. 13 is a conceptual diagram of a light sensor device 200 according to a first application example. The light sensor device 200 illustrated in FIG. 13 has a light sensor unit 110 and a semiconductor circuit 120.

For example, the light sensor unit 110 has a plurality of light detection elements 100. Each of the light detection elements 100 is the light detection element described above. Each of the light detection elements 100 functions as a light sensor. The light detection elements 100 may be operated in the second operation example. For example, the light detection elements 100 are two-dimensionally arranged in a matrix shape. Each of the light detection elements 100 is connected to a first selection line extending in a row direction and a second selection line extending in a column direction. The light sensor unit 110 detects light using the light detection elements 100 and replaces the light with an electrical signal.

For example, the semiconductor circuit 120 is disposed on the outward side of the outer circumference of the light sensor unit 110. In addition, the semiconductor circuit 120 may be formed on a circuit substrate 101 (which will be described below) and may be at a position overlapping the light sensor unit 110 in the z direction.

The semiconductor circuit 120 is electrically connected to each of the light detection elements 100. The semiconductor circuit 120 computes an electrical signal sent from the light sensor unit 110. For example, the semiconductor circuit 120 has a row decoder 121 and a column decoder 122. The positions of the light detection elements 100 which have detected light are specified using row decoder 121 and the column decoder 122. In addition to the row decoder 121 and the column decoder 122, the semiconductor circuit 120 may have a memory, a computation circuit, a resistor, and the like.

FIG. 14 illustrates an example of a specific constitution of a light sensor unit. The light sensor unit 110 illustrated in FIG. 14 has a plurality of pixels p1. For example, each of the pixels p1 has a red sensor 100R, a green sensor 100, a blue sensor 100B, an infrared sensor 100IR, and an ultraviolet sensor 100UV. Each of the red sensor 100R, the green sensor 100G, the blue sensor 100B, the infrared sensor 100IR, and the ultraviolet sensor 100UV is constituted of the light detection element 100. In the light sensor unit 110 illustrated in FIG. 14, an example in which two green sensors 100G having high visual sensitivity are disposed in one pixel p1 has been described, but it is not limited to this case. For example, at least one of the infrared sensor 100IR and the ultraviolet sensor 100UV may be excluded.

Each of the red sensor 100R, the green sensor 100G, and the blue sensor 100B detects light in a particular wavelength range of a wavelength range of 380 nm or more and less than 800 nm (which will hereinafter be referred to as first wavelength ranges). For example, the blue sensor 100B detects light in a wavelength range of 380 nm or more and less than 490 nm. For example, the green sensor 100G detects light in a wavelength range of 490 nm or more and less than 590 nm. For example, the red sensor 100R detects light in a wavelength range of 590 nm or more and 800 nm or less. The infrared sensor 100IR detects light in a particular wavelength range of a wavelength range of 800 nm or more and 1 mm or less (which will hereinafter be referred to as a second wavelength range). The ultraviolet sensor 100UV detects light in a particular wavelength range of a wavelength range of 200 nm or more and less than 380 nm (which will hereinafter be referred to as third wavelength ranges).

In the example illustrated in FIG. 14, for example, the red sensors 100R, the green sensors 100G, and the blue sensors 100B can be regarded as first light detection elements, the infrared sensors 100IR can be regarded as second light detection elements, and the ultraviolet sensors 100UV can be regarded as third light detection elements. The first light detection elements are light detection elements in which the magnetic elements 10 are disposed at the focal positions of light in the first wavelength range focused by the meta-lens 20. The second light detection elements are light detection elements in which the magnetic elements 10 are disposed at the focal positions of light in the second wavelength range focused by the meta-lens 20. The third light detection elements are light detection elements in which the magnetic elements 10 are disposed at the focal positions of light in the third wavelength range focused by the meta-lens 20. The first wavelength range, the second wavelength range, the third wavelength range are wavelength ranges different from each other.

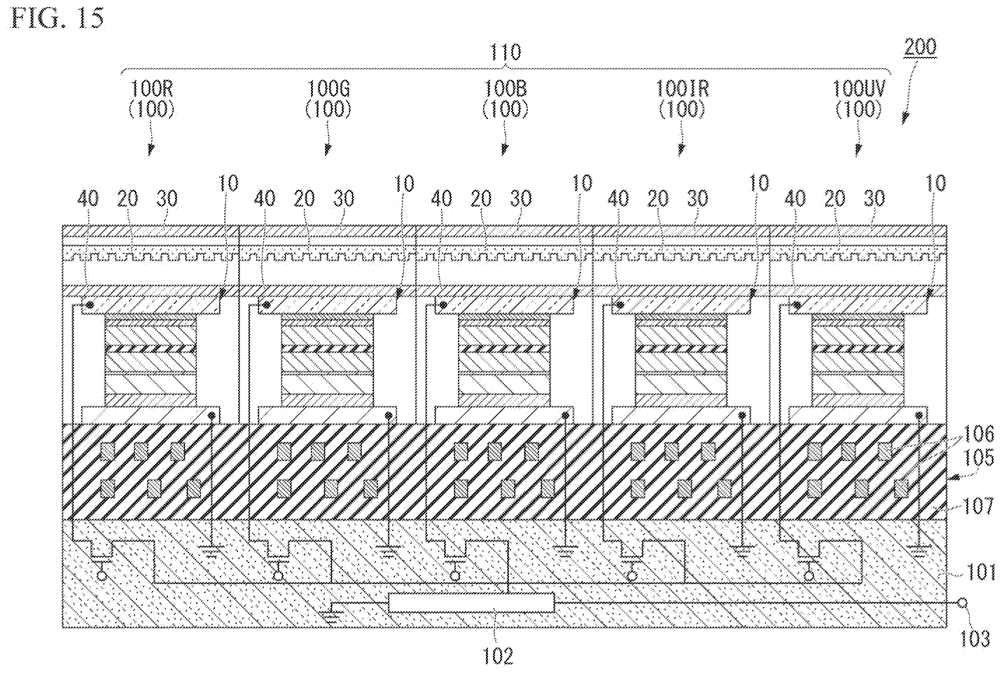

FIG. 15 is a conceptual diagram of a cross section of the light sensor device 200 according to the first embodiment. For example, the light sensor device 200 has the circuit substrate 101, a wiring layer 105, and a plurality of light detection elements 100. Each of the wiring layer 105 and the light detection elements 100 are formed on the circuit substrate 101.

The semiconductor circuit 120 described above is formed on the circuit substrate 101. For example, the circuit substrate 101 has an analog-digital convener 102 and an output terminal 103. An electrical signal sent from the light detection elements 100 is replaced with digital data by the analog-digital converter 102 and is output from the output terminal 103.

The wiring layer 105 has a plurality of wirings 106. An interlayer insulating film 107 is provided between the wirings 106. The wirings 106 electrically connect each of the light detection elements 100 to the circuit substrate 101 and connect computation circuits formed on the circuit substrate 101 to each other. For example, each of the light detection elements 100 is connected to the circuit substrate 101 via a penetration wiring penetrating the interlayer insulating film 107 in the z direction. Noise can be reduced by shortening the distance between the wiring between each of the light detection elements 100 and the circuit substrate 101.

The wirings 106 have conductivity. For example, the wirings 106 are made of Al, Cu, or the like. The interlayer insulating film 107 is an insulator insulating the wirings of multilayer wirings from each other and the elements from each other. For example, the interlayer insulating film 107 is made of oxide, nitride, or oxynitride of Si, Al, or Mg, and a material similar to that of the insulating layer 90 can be used.

In addition, the wavelength filter 40 of each of the red sensor 100R, the green sensor 100G, the blue sensor 100B, the infrared sensor 100IR, and the ultraviolet sensor 100UV varies in wavelength range of light transmitted therethrough. For example, the wavelength filter 40 of the red sensor 100R allows light in wavelength ranges of 590 nm or more and less than 800 nm to be transmitted therethrough. For example, the wavelength filter 40 of the green sensor 100G allows light in wavelength ranges of 490 nm or and less than 590 nm to be transmitted therethrough. For example, the wavelength filter 40 of the blue sensor 100B allows light in wavelength ranges of 380 nm or more and less than 490 nm to be transmitted therethrough. For example, the wavelength filter 40 of the infrared sensor 100IR allows light in a particular wavelength range of a wavelength range of 800 nm or more and 1 mm or less to be transmitted therethrough. For example, the wavelength filter 40 of the ultraviolet sensor 100UV allows light in a particular wavelength range of a wavelength range of 200 nm or more and less than 380 nm to be transmitted therethrough.

In the light detection elements 100 constituting one pixel p1, the distances between the magnetic elements 10 and the meta-lens 20 may be equivalent to each other. In this case, at least one light detection element 100 constituting one pixel p1 among the light detection elements 100 differs from another light detection element 100 constituting one pixel p1 in constitutions of the nanostructures 21 in the meta-lens 20. For example, the constitutions of the nanostructures 21 in each meta-leas 20 of the red sensor 100R, the green sensor 100G, the blue sensor 100B, the infrared sensor 100IR, and the ultraviolet sensor 100UV differ from each other. For example, the constitutions of the nanostructures 21 include the size of the shape of each of the nanostructures 21 in a plan view, the disposition intervals between nanostructures, and the like. For example, the constitutions of the nanostructures 21 in each meta-lens 20 may be set such that the focal distance of the meta-lens 20 of the red sensor 100R with respect to light having a wavelength of 633 nm, the focal distance of the meta-lens 20 of the green sensor 100G with respect to light having a wavelength of 530 nm, the focal distance of the meta-lens 20 of the blue sensor 100B with respect to light having a wavelength of 430 nm, the focal distance of the meta-lens 20 of the infrared sensor 100IR with respect to light having a wavelength of 1530 nm, and the focal distance of the meta-lens 20 of the ultraviolet sensor 100UV with respect to light having a wavelength of 290 nm become equivalent to each other.

In the light detection elements 100 illustrated in FIG. 15, one magnetic element 10 is disposed below one meta-lens 20, but a plurality of magnetic elements 10 may be disposed below one meta-lens 20.

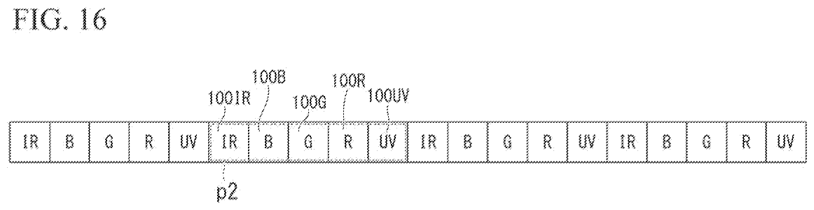

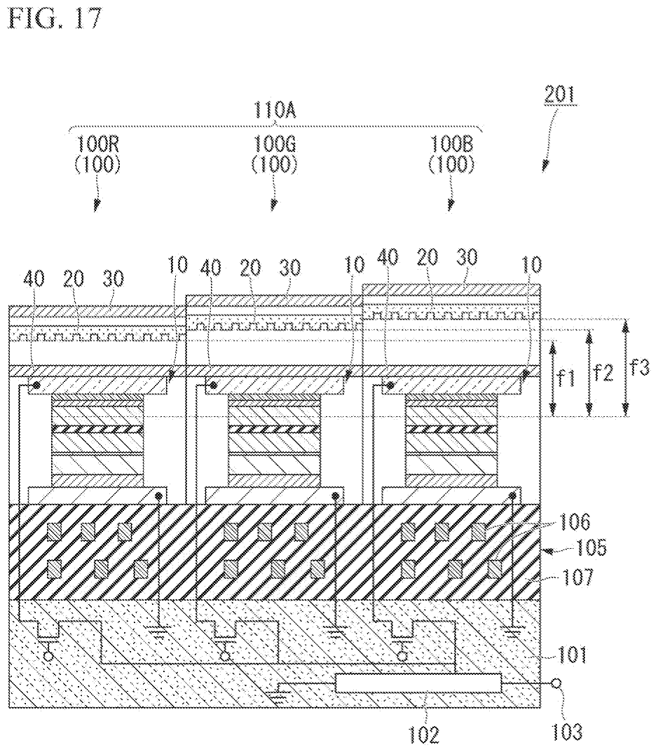

In addition, thus far, an example in which the light detection elements 100 are two-dimensionally arranged has been described. However, the light detection elements 100 may be one-dimensionally arranged as illustrated in FIG. 16. In FIG. 16, an example in which one pixel p2 is constituted of the red sensor 100R, the green sensor 100G, the blue sensor 100B, the infrared sensor 100IR, and the ultraviolet sensor 100UV which are one-dimensionally arranged has been described. However, one or more of these may not be provided. In addition, a plurality of light detection elements 100 may detect light in the same wavelength range, and the wavelength range of light detected by each of the light detection elements 100 is not particularly limited.

In addition, as in a light sensor device 201 illustrated in FIG. 17, a light sensor unit 110A may have light detection elements 100 of which the distances between the magnetic element 10 and the meta-lens 20 differ from each other. For example, at least one of the light detection elements 100 constituting one pixel p1 may differ from another light detection element 100 constituting one pixel p1 in distance between the meta-lens 20 and the magnetic element 10. In this case, the constitutions of the nanostructures 21 in the meta-lens 20 may be the same between the light detection elements 100 constituting one pixel p1.

For example, in the red sensor 100R, the green sensor 100G, and the blue sensor 100B, the distance between the meta-lens 20 and the magnetic element 10 differ from each other. In the meta-lens 20 having a certain one constitution, the focal distance of the meta-lens 20 with respect to the light L varies depending on the wavelength of the light L. In the red sensor 100R, the magnetic element 10 (the first ferromagnetic layer 1 in the example of FIG. 17) and the meta-lens 20 are separated from each other by a first focal distance f1. In the green sensor 100G, the magnetic element 10 (the first ferromagnetic layer 1 in the example of FIG. 17) and the meta-lens 20 are separated from each other by a second focal distance f2. In the blue sensor 100B, the magnetic element 10 (the first ferromagnetic layer 1 in the example of FIG. 17) and the meta-lens 20 are separated from each other by a third focal distance f3. The first focal distance f1 is a focal distance of the meta-lens 20 with respect to light having a particular wavelength (for example, light in a wavelength of 633 nm) of light in a wavelength range of 590 nm or more and 800 nm or less (red light). The second focal distance f2 is a focal distance of the meta-lens 20 with respect to light having a particular wavelength (for example, light in a wavelength of 530 nm) of light in a wavelength range of 490 nm or more and 590 nm or less (green light). The third focal distance f3 is a focal distance of the meta-lens 20 with respect to light having a particular wavelength (for example, light in a wavelength of wavelength 530 nm) of light in a wavelength range of 380 nm or more and 490 nm or less (blue light). The first focal distance f1 is shorter than the second focal distance f2, and the second focal distance f2 is shorter than the third focal distance f3.

The light sensor devices 200 and 201 measure an output voltage from the magnetic element 10 of each of the light detection elements 100 in the light sensor units 110 and 110A (resistance value of the magnetic element 10) together with positional information obtained by the row decoder 121 and the column decoder 122 and reads the intensity of light applied to the light sensor unit 110. For example, the light sensor devices 200 and 201 are used in image sensors and the like. Such image sensors can be used in information terminal devices such as smartphones, tablet computers, personal computers, and digital cameras.

Thus far, examples of the light sensor devices 200 and 201 have been described. However, the light sensor device is not limited to these examples. For example, in the light sensor units 110 and 110A, when the meta-lens 20 is used as illustrated in FIG. 2, or when light incident on the light detection elements 100 is polarized light such as laser light, the polarization filter 30 may not be provided. In addition, the focal distance of light incident on one meta-lens 20 varies depending on the wavelength. For this reason, the meta-lens 20 itself functions as a wavelength filter for limiting the wavelength range of light applied to the magnetic element 10 with a significant intensity. When an effect of filtering a wavelength by the meta-lens 20 is sufficient, the wavelength filter 40 may not be provided.

### Second Application Example

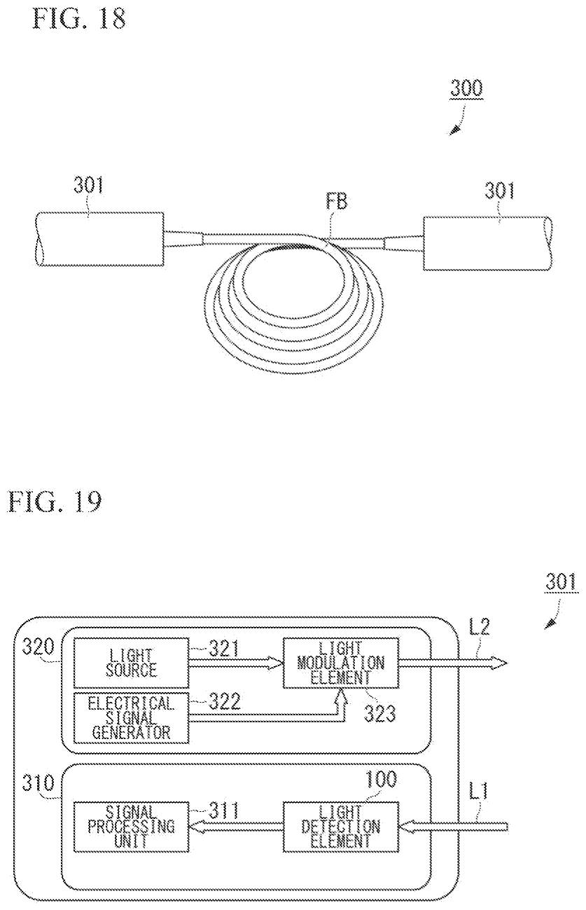

FIG. 18 is a conceptual diagram of a communication system 300 according to a second application example. The communication system 300 illustrated in FIG. 18 includes a plurality of transceiver devices 301 and optical fibers FB connecting the transceiver devices 301 to each other. For example, the communication system 300 can be used for short/intermediate-range communication within a data center and between data centers and long-distance communication such as inter-city communication. For example, the transceiver devices 301 are installed inside data centers. For example, the optical fibers FB connect data centers to each other. For example, the communication system 300 performs communication between the transceiver devices 301 via the optical fibers FB. The communication system 300 may perform communication between the transceiver devices 301 by radio without having the optical fibers FB therebetween.

FIG. 19 is a block diagram of the transceiver device 301 according to the second application example. The transceiver device 301 includes a receiving device 310 and a transmitting device 320. The receiving device 310 receives an optical signal L1, and the transmitting device 320 transmits an optical signal L2. Light used for transceiving between the transceiver devices 301 via the optical fibers FB is near infrared light having a wavelength of 1000 nm or more and 2000 nm or less, for example.

For example, the receiving device 310 includes a light detection element 100 and a signal processing unit 311. The light detection element 100 is the light detection element described above and converts the optical signal L1 into an electrical signal. Light including the optical signal L1 with light intensity change is applied to the light detection element 100. In addition, light which passes through a waveguide may be applied to the light detection element 100. Light applied to the light detection element 100 (magnetic element 10) is laser light, for example. The signal processing unit 311 performs processing of an electrical signal converted by the light detection element 100. The signal processing unit 311 receives a signal included in the optical signal L1 by processing an electrical signal generated from the light detection element 100.

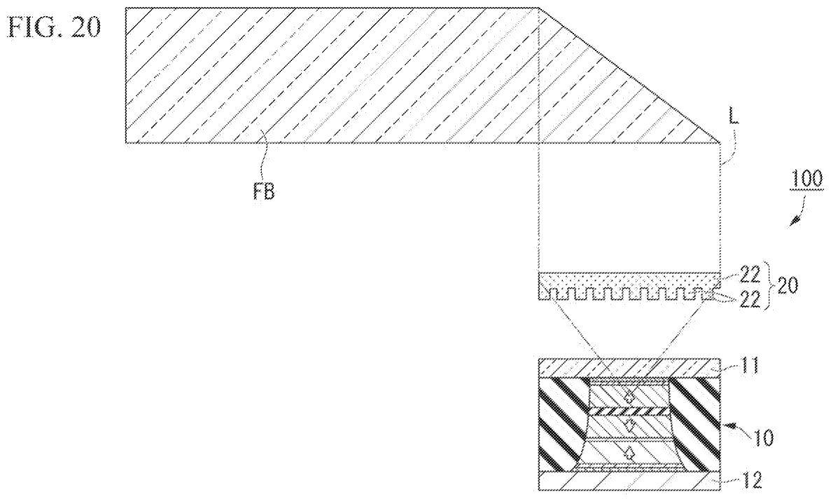

FIG. 20 is an enlarged schematic view of a part in the vicinity of the light detection element 100 of the communication system 300 according to the second application example. For example, light which has been propagated in the optical fiber FB, which is a waveguide, is concentrated by the meta-lens 20 and reaches the magnetic element 10. Similar to FIG. 6, the light detection element 100 illustrated in FIG. 20 may have the polarization filter 30.

For example, the transmitting device 320 includes a light source 321, an electrical signal generator 322, and a light modulation element 323. For example, the light source 321 is a laser element. For example, the light source 321 may be an LED element. Light emitted by the light source 321 may be light having a single wavelength (monochromatic light). The light source 321 may be provided outside the transmitting device 320. The electrical signal generator 322 generates an electrical signal based on transmission information. The electrical signal generator 322 may be integrated with a signal conversion element of the signal processing unit 311. The light modulation element 323 modulates light output from the light source 321 and outputs the optical signal L2 based on an electrical signal generated by the electrical signal generator 322.

In addition, thus far, an example in which a transceiver device is applied to the communication system 300 illustrated in FIG. 18 has been described. However, a communication system is not limited to this case.

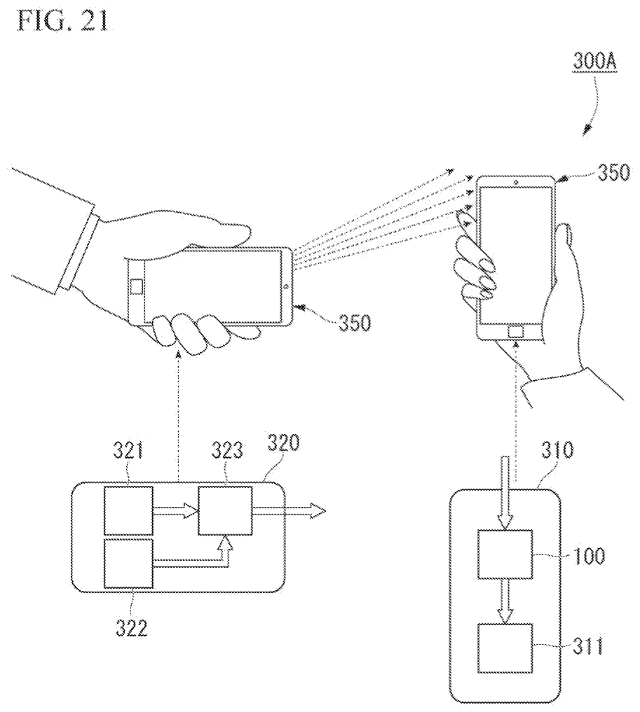

For example, FIG. 21 is a conceptual diagram of another example of a communication system. A communication system 300A illustrated in FIG. 21 performs communication between two portable terminal devices 350. For example, the portable terminal devices 350 are smartphones, tablet computers, or the like.

Each of the portable terminal devices 350 includes the receiving device 310 and the transmitting device 320. The receiving device 310 of the other portable terminal device 350 receives an optical signal transmitted from the transmitting device 320 of one portable terminal device 350. Transceiving of an optical signal between the portable terminal devices 350 is performed by radio. Light used for transceiving between the portable terminal devices 350 is visible light, for example. For example, light used for transceiving between the portable terminal devices 350 may be near infrared light having a wavelength of 800 nm or more and 2500 nm or less. The light detection element described above is applied as the light detection element 100 of each receiving device 310. In this case, light including an optical signal transmitted from the transmitting device 320 may be propagated in the waveguide provided in the receiving device 310 and applied to the light detection element 100 or may be applied to the light detection element 100 without going through a waveguide.

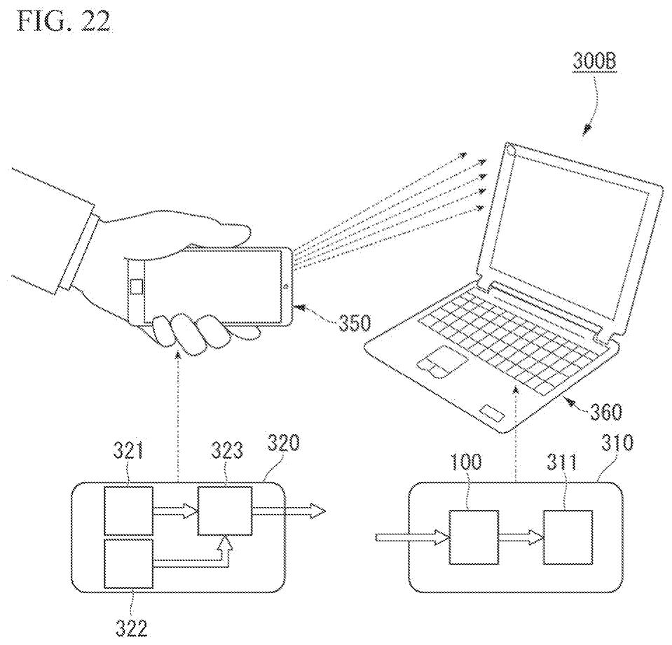

In addition, for example, FIG. 22 is a conceptual diagram of another example of a communication system. A communication system 300B illustrated in FIG. 22 performs communication between the portable terminal devices 350 and an information processing device 360. For example, the information processing device 360 is a personal computer.

The portable terminal devices 350 includes the transmitting device 320, and the information processing device 360 includes the receiving device 310. An optical signal transmitted from the transmitting device 320 of the portable terminal devices 350 is received by the receiving device 310 of the information processing device 360. Transceiving of an optical signal between the portable terminal devices 350 and the information processing device 360 is performed by radio. Light used for transceiving between the portable terminal devices 350 and the information processing device 360 is visible light, for example. Light used for transceiving between the portable terminal devices 350 and the information processing device 360 may be near infrared light having a wavelength of 800 nm or more and 2500 nm or less, for example. The light detection element described above is applied as the light detection element 100 of the receiving device 310. The light detection element, the light sensor unit, and the receiving device according to the foregoing embodiment operate in accordance with a novel principle.

While embodiments of the invention have been described and illustrated above, it should be understood that these are exemplary of the invention and are not to be considered as limiting. Additions, omissions, substitutions, and other modifications can be made without departing from the spirit or scope of the disclosure. Accordingly, the invention is not to be considered as being limited by the foregoing description, and is only limited by the scope of the appended claims.

### EXPLANATION OF REFERENCES

1 First ferromagnetic layer

2 Second ferromagnetic layer

3 Spacer layer

4 Buffer layer

5 Seed layer

6 Third ferromagnetic layer

7 Magnetic coupling layer

8 Perpendicular magnetization inducing layer

9 Cap layer

10 Magnetic element

11 First electrode

12 Second electrode

15 Laminate

20, 20A Meta-lens

21, 21A Nanostructure

22 Base

23, 23A Unit

30 Polarization filter

40 Wavelength filter

90, 91 Insulating layer

100 Light detection element

100B Blue sensor

100G Green sensor

100R Red sensor

100IK Infrared sensor

100UV Ultraviolet sensor

101 Circuit substrate

102 Analog-digital converter

103 Output terminal

105 Wiring layer

106 Wiring

107 Interlayer insulating layer

110 Sensor unit

120 Semiconductor circuit

121 Row decoder

122 Column decoder

200, 201 Light sensor device

300, 300A, 300B Communication system

301 Transceiver device

310 Receiving device

311 Signal processing unit

320 Transmitting device

321 Light source

322 Electrical signal generator

323 Light modulation element

350 Information terminal device

360 Information processing device

L Light

L1, L2 Optical signal

P1, p2 Pixel

What is claimed is:

1. A light detection element comprising:
a meta-lens that includes nanostructures which are two-dimensionally arranged; and
a magnetic element that includes a first ferromagnetic layer, a second ferromagnetic layer, and a spacer layer sandwiched between the first ferromagnetic layer and the second ferromagnetic layer,
wherein light which passes through the meta-lens is applied to the magnetic element.

2. The light detection element according to claim 1,
wherein the meta-lens has a first region when an arrangement surface on which the nanostructures are arranged is viewed in a plan view, and
an area of each of nanostructures provided in the first region in the plan view decreases toward an outward side from a center of the first region.

3. The light detection element according to claim 2,
wherein the meta-lens further has an annular region on the outward side of the first region when the arrangement surface on which the nanostructures are arranged is viewed in the plan view, and
an area of each of nanostructures provided in the annular region in the plan view decreases toward an outer circumferential side from an inner circumferential side of the annular region.

4. The light detection element according to claim 1,
wherein when an arrangement surface on which the nanostructures are arranged is viewed in a plan view, a shape of each of the nanostructures in the plan view has a longitudinal direction and a transverse direction, and
a disposition angle of the longitudinal direction of at least one of the nanostructures is different from a disposition angle of the longitudinal direction of another nanostructure.

5. The light detection element according to claim 1,
wherein the magnetic element is disposed at a focal position of the light focused by the meta-lens.

6. The light detection element according to claim 5,
wherein the light is light in a particular wavelength range of a wavelength range of 380 nm or more and less than 800 nm.

7. The light detection element according to claim 5,
wherein the light is light in a particular wavelength range of a wavelength range of 800 nm or more and 1 mm or less.

8. The light detection element according to claim 5,
wherein the light is light in a particular wavelength range of a wavelength range of 200 nm or more and less than 380 nm.

9. A light sensor unit comprising:
a plurality of light detection elements,
wherein each of the light detection elements is the light detection element according to claim 1.

10. The light sensor unit according to claim 9,
wherein the light detection elements include at least a first light detection element and a second light detection element,
in the first light detection element, the magnetic element is disposed at a focal position of light in a first wavelength range focused by the meta-lens, and
in the second light detection element, the magnetic element is disposed at a focal position of light in a second wavelength range different from the first wavelength range focused by the meta-lens.

11. The light sensor unit according to claim 10,
wherein the first wavelength range is a particular wavelength range of a wavelength range of 380 nm or more and less than 800 nm, and
wherein the second wavelength range is a particular wavelength range of a wavelength range of 800 nm or more and 1 mm or less.

12. The light sensor unit according to claim 10,
wherein the light detection elements further has a third light detection element,
in the third light detection element, the magnetic element is disposed at a focal position of light in a third wavelength range different from the first wavelength range and the second wavelength range focused by the meta-lens, and
the third wavelength range is a particular wavelength range of a wavelength range of 200 nm or more and less than 380 nm.

13. The light sensor unit according to claim 9,
wherein the light detection elements are one-dimensionally arranged.

14. The light sensor unit according to claim 9,
wherein the light detection elements are two-dimensionally arranged.

15. The light sensor unit according to claim 9,
wherein at least one light detection element constituting one pixel among the light detection elements differs from another light detection element constituting the one pixel in a constitution of the nanostructures in the meta-lens.

16. The light sensor unit according to claim 9,
wherein at least one light detection element constituting one pixel among the light detection elements differs from another light detection element constituting the one pixel in a distance between the meta-lens and the magnetic element.

17. A receiving device comprising:
the light detection element according to claim 1.

18. The light detection element according to claim 2,
wherein the magnetic element is disposed at a focal position of the light focused by the meta-lens.

19. The light detection element according to claim 3,
wherein the magnetic element is disposed at a focal position of the light focused by the meta-lens.

20. The light detection element according to claim 4,
wherein the magnetic element is disposed at a focal position of the light focused by the meta-lens.
